(19) United States
(12) Patent Application Publication
(10) Pub. No.: US 2025/0315577 A1
(43) Pub. Date: Oct. 9, 2025

(54) SIMULATION METHOD AND SYSTEM BASED ON MACHINE LEARNING MODEL WITH REDUCED TRAINING REQUIREMENTS

(71) Applicant: Samsung Electronics Co., Ltd., Suwon-si (KR)

(72) Inventors: Kyeyeop Kim, Suwon-si (KR); Sanghoon Myung, Suwon-si (KR); Gijae Kang, Suwon-si (KR); Jaehoon Jeong, Suwon-si (KR); Yunji Choi, Suwon-si (KR); Songyi Han, Suwon-si (KR)

(73) Assignee: Samsung Electronics Co., Ltd., Suwon-si (KR)

(21) Appl. No.: 19/024,509

(22) Filed: Jan. 16, 2025

(30) Foreign Application Priority Data
Apr. 3, 2024 (KR) 10-2024-0045575
May 31, 2024 (KR) 10-2024-0071817

(51) Int. Cl. G06F 30/27

(52) U.S. Cl. CPC G06F 30/27

(57) ABSTRACT

A method of performing a process simulation of a semiconductor device may include obtaining a target parameter and first state profile data corresponding to an initial value; and generating second state profile data corresponding to the target parameter from the first state profile data, based on a machine learning model. Each of the first state profile data and the second state profile data may represent an attribute profile of a corresponding state of a semiconductor device.

### CROSS-REFERENCE TO RELATED APPLICATION

This application is based on and claims priority under 35 U.S.C. § 119 to Korean Patent Application Nos. 10-2024-0045575, filed on Apr. 3, 2024, and 10-2024-0071817, filed on May 31, 2024, in the Korean Intellectual Property Office, the disclosure of which are incorporated by reference herein in its entirety.

### TECHNICAL FIELD

The inventive concept relates to a simulation method and system based on a machine learning model, and more particularly, to a simulation method and system which may improve machine learning models and replace a technology computer aided design (TCAD) simulation.

### BACKGROUND

Design simulators such as TCAD simulators may be used for predicting characteristics of a semiconductor produced in fields such as semiconductor manufacturing. To accurately predict a characteristic of a semiconductor by using a design simulator, output data representing the characteristic of the semiconductor may be observed by inputting input data (representing a layout of the semiconductor, doping techniques including ion implantation, and/or a doping profile) to the design simulator while converting the input data, and calibration for allowing the output data to match target output data may be performed. However, the number of factors to be considered in simulation may increase as a semiconductor manufacturing process is more complicated, and it may be more difficult to accurately predict a characteristic of a semiconductor by using a design simulator.

### SUMMARY

The inventive concept provides a simulation method and system which may replace a technology computer aided design (TCAD) simulation of the related art.

A method of performing a process simulation of a semiconductor device according to an embodiment may include executing, by at least one processor, computer program instructions to perform operations comprising obtaining a target parameter and first state profile data corresponding to an initial value; and generating second state profile data corresponding to the target parameter from the first state profile data based on a machine learning model, where each of the first state profile data and the second state profile data may represent an attribute profile of a corresponding state of a semiconductor device.

A system according to an embodiment may include at least one processor and a non-transitory computer readable storage medium configured to store computer program instructions allowing the at least one processor to perform the method of performing the process simulation of the semiconductor device, when executed by the at least one processor.

A non-transitory computer-readable storage medium according to an embodiment may include computer program instructions, where the instructions may be configured to allow at least one processor to perform the method of performing the process simulation of the semiconductor device, when executed by the at least one processor.

A computing system according to an embodiment may include a processing circuit configured to obtain a target parameter and first state profile data corresponding to an initial value and generate second state profile data corresponding to the target parameter from the first state profile data based on a machine learning model, where each of the first state profile data and the second state profile data may represent an attribute profile of a corresponding state of a semiconductor device.

### BRIEF DESCRIPTION OF THE DRAWINGS

Embodiments will be more clearly understood from the following detailed description taken in conjunction with the accompanying drawings in which:

FIG. 1 is a block diagram of a computing system according to an embodiment;

FIG. 2 is a flowchart illustrating an example of an operation of a computing system according to an embodiment;

FIG. 3 is a diagram illustrating a machine learning model according to an embodiment;

FIG. 4 is a diagram illustrating an operation of a pre-processing module according to an embodiment;

FIG. 5 is a diagram illustrating an operation of an encoding module according to an embodiment;

FIG. 6 is a diagram illustrating a Fourier layer module according to an embodiment;

FIG. 7 is a diagram illustrating a Fourier operating module according to an embodiment;

FIG. 8 is a diagram illustrating an operation of a Fourier operating module according to an embodiment;

FIG. 9 is a diagram illustrating a Fourier layer module according to another embodiment;

FIG. 10 is a flowchart illustrating an example of an operation of a computing system according to another embodiment;

FIG. 11 is a flowchart illustrating in more detail operation S220 of FIG. 10;

FIG. 12 is a graph showing an output value with respect to an input value where a machine learning model according to an embodiment is outside a learning range;

FIG. 13 is a diagram to describe a convergence rate of a machine learning model according to an embodiment;

FIG. 14 is a block diagram illustrating a computing system according to an embodiment; and

FIG. 15 is a block diagram illustrating a system according to an embodiment.

### DETAILED DESCRIPTION OF THE EMBODIMENTS

The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “previous” may be used herein to refer to prior elements, calculations, or modules that precedes the current one in a series, sequence, or timeline. The term “corresponding” may be used herein to distinguish between a particular component and another component wherein the other component is related to or affiliated with the particular component, for example, sequentially or temporally.

“Modules” described herein may correspond to hardware, software, or a combination of hardware and software, such as a circuit, which is included in a computing system. Hardware may include at least one of a programmable component such as a central processing unit (CPU), a digital signal processor (DSP), or a graphics processing unit (GPU), a reconfigurable component such as a field programmable gate array (FPGA), and a component, providing a stationary function, such as an intellectual property (IP) block. Software may include at least one of a series of instructions executable by a programmable component and code capable of being converted into a series of instructions by a compiler and may be stored in a non-transitory storage medium.

Herein, a “machine learning model” may have a non-transitory structure capable of training. For example, a machine learning model may include an artificial neural network, a decision tree, a support vector machine, a Bayesian network, and/or a genetic algorithm. Hereinafter, a machine learning model will be mainly described with reference to an artificial neural network, but embodiments are not limited thereto. An artificial neural network, as a non-transitory example, may include a convolution neural network CNN), region with convolution neural network (R-CNN), a region proposal network (RPN), a recurrent neural network (RNN), a stacking-based deep neural network (S-DNN), a state-space dynamic neural network (S-SDNN), a deconvolution network, a deep belief network (DBN), a restricted Boltzmann machine (RBM), a fully convolutional network, long short-term memory (LSTM) network, a classification network, and/or the like. Herein, a machine learning model may be simply referred to as a model. The model can be constructed as multiple parallel models that can execute in parallel.

Hereinafter, various embodiments will be described with reference to the accompanying drawings.

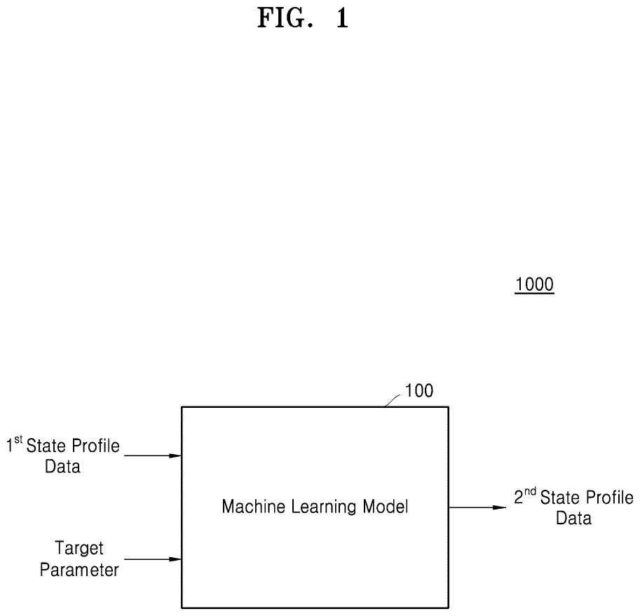

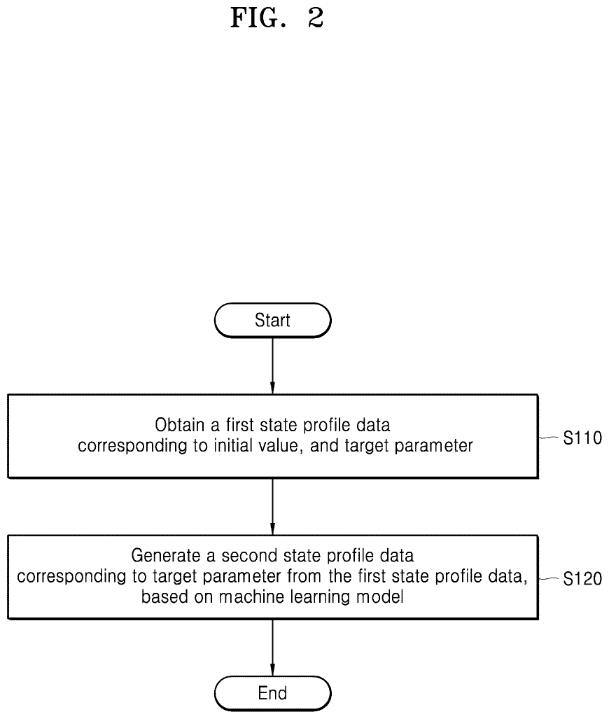

FIG. 1 is a block diagram of a computing system 1000 according to an embodiment. FIG. 2 is a flowchart illustrating an example of an operation of the computing system 1000 according to an embodiment.

With reference to FIGS. 1 and 2, a method of performing a process simulation by using a machine learning model 100 may be described. Herein, attributes of a semiconductor device formed through a semiconductor process may be described for example, but embodiments are not limited thereto.

In some embodiments, the method of performing the process simulation by using the machine learning model 100 may be performed by the computing system 1000 of FIG. 1. For example, the computing system 1000 of FIG. 1 may include at least one module or circuit implemented with hardware, software, or a combination of hardware and software, and the computing system 1000 may implement the machine learning model 100 by using at least one module or circuit and may thus perform a process simulation.

Referring to FIGS. 1 and 2, in operation S110, the computing system 1000 may obtain a target parameter and first state profile data corresponding to an initial value.

In operation S120, the computing system 1000 may generate second state profile data corresponding to the target parameter from the first state profile data, based on the machine learning model 100.

Here, each of the first state profile data and the second state profile data may represent an attribute profile of a corresponding state or characteristic (such as material and/or operating characteristics) of a semiconductor device.

In an embodiment, state profile data may represent a density of electrons n distributed in a transistor having a certain state, a density of holes p distributed in the transistor, and/or an electrostatic potential ϕ distributed in the transistor.

Here, a factor for determining the certain state of the transistor may be a contact voltage V and/or a doping profile N of the transistor.

For example, the contact voltage V may denote a voltage applied to a gate electrode of the transistor, a voltage applied to a source electrode of the transistor, and/or a voltage applied to a drain electrode of the transistor.

Also, in order to generate the state profile data described above, the computing system 1000 may calculate a solution of a drift-diffusion equation. The drift-diffusion equation may provide a representation of how charged particles move in semiconductor devices.

That is, based on the drift-diffusion equation, the computing system 1000 may calculate the density of electrons n distributed in the transistor, the density of holes p distributed in the transistor, and/or the electrostatic potential ϕ distributed in the transistor, which are based on the contact voltage V and/or the doping profile N of the transistor.

For example, the computing system 1000 may calculate the solution of the drift-diffusion equation, based on the contact voltage V and/or the doping profile N of the transistor, and thus, may generate the state profile data representing the density of electrons n distributed in the transistor, the density of holes p distributed in the transistor, and/or the electrostatic potential ϕ distributed in the transistor.

Hereinafter, an example where the doping profile N of the transistor is predetermined will be described. For example, a doping profile may be predetermined based on process parameters (for example, a dopant, a dose, a tilt, injection energy, and a temperature).

The target parameter of operation S110 described above with reference to FIGS. 1 and 2 may be a target contact voltage Vᵢ.

Also, an initial value uᵢ₋₁ represented by the first state profile data may be a set uᵢ₋₁(ϕᵢ₋₁, nᵢ₋₁; pᵢ₋₁; N) of an electrostatic potential, a density of electrons, and a density of holes each distributed in a transistor, which are based on a predetermined doping profile N and a current contact voltage Vᵢ₋₁.

That is, the first state profile data may include the predetermined doping profile N, the current contact voltage Vᵢ₋₁, and the initial value uᵢ₋₁(ϕᵢ₋₁, nᵢ₋₁; pᵢ₋₁; N).

The second state profile data corresponding to the target parameter of operation S120 described above with reference to FIGS. 1 and 2 may represent a target value uᵢ.

Here, the target value uᵢ may be a set uᵢ(ϕᵢ, nᵢ, pᵢ; N) of an electrostatic potential, a density of electrons, and a density of holes each distributed in the transistor, which are based on the predetermined doping profile N and a target contact voltage Vᵢ.

That is, the second state profile data may include the target value uᵢ₋₁(ϕᵢ₋₁, nᵢ₋₁; pᵢ₋₁; N).

Furthermore, a technology computer aided design (TCAD) simulator may receive only an initial voltage and a doping profile as an input value, in contrast to the computing system 1000 which according to an embodiment may receive the predetermined doping profile N, the current contact voltage Vᵢ₋₁, and the initial value uᵢ₋₁(ϕᵢ₋₁, nᵢ₋₁; pᵢ₋₁; N) as an input value and may use an artificial neural network pre-trained through operator learning such as a neural operator to directly learn a solution of a drift-diffusion equation. The term “operator learning” as used herein, may refer to a machine learning technique which involves mathematical operators, for example, differential operators which may be used to learn mappings between functions. This technique may be used in scientific computing and computer modeling of complex physical systems, where a neural operator may leverage deep learning architectures such as artificial neural networks to learn complex mappings. In contrast to other machine learning techniques, where a learning operator may be used to map functions from vectors or discrete data points, a neural operator may learn operators which can evaluate functions in spaces outside the learning range of non-neural operators. Thus, even when state profile data outside a learning range is input, the computing system 1000 according to an embodiment may accurately calculate state profile data. As used herein, the “learning range” may refer to the scope of data and input values on which the model, simulator, or system has been trained.

In detail, a TCAD simulator according to a comparative example may learn an operation of a solution of the drift-diffusion equation while constantly applying a voltage to a contact, instead of directly solving the drift-diffusion equation which is a partial differential equation (PDE), and thus, may perform a simulation based on a data-driven method. Therefore, the TCAD simulator according to the comparative example may decrease in prediction performance in a region which is not trained, that is, for data on which the TCAD simulator has not been trained.

On the other hand, the computing system 1000 according to an embodiment may use an artificial neural network pre-trained through operator learning which directly learns a solution of the drift-diffusion equation, which is a PDE, and thus, may maintain prediction performance in a region which is not trained, for example, including data on which the computing system 1000 has not been trained. In some embodiments, the operator learning as described herein may be configured to utilize fewer memory resources, for example, by removing nodes or paths through one or more layers of the artificial neural network, e.g., by setting one or more parameters to zero and/or otherwise excluding nodes when performing computations.

That is, comparing with the TCAD simulator according to the comparative example, the computing system 1000 according to an embodiment may be improved in extrapolation performance.

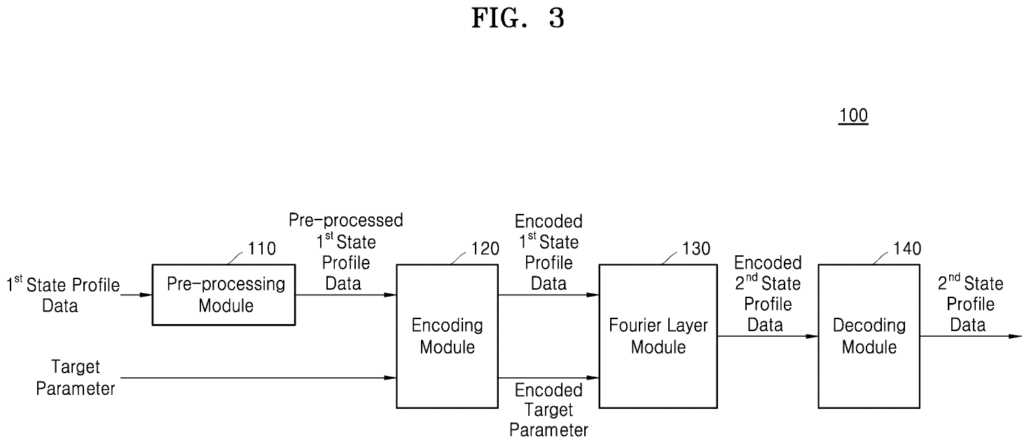

Hereinafter, a method of using, by the computing system 1000, an artificial neural network pre-trained through operator learning which directly learns a solution of the drift-diffusion equation which is a PDE will be described in detail with reference to FIGS. 3 to 9.

FIG. 3 is a diagram illustrating a machine learning model 100 according to an embodiment.

Referring to FIG. 3, the machine learning model 100 may include a pre-processing module 110, an encoding module 120, a Fourier layer module 130, and a decoding module 140.

Here, the Fourier layer module 130 may be implemented with an artificial neural network, and the artificial neural network implementing the Fourier layer module 130 may be referred to as an artificial neural network in an offline period and may be referred to as a pre-trained artificial neural network in an online period.

For example, the offline period may denote a period where data or a task is previously prepared or processed. For example, a process of training the artificial neural network may be included in the offline period. That is, in the offline period, the computing system 1000 may train the artificial neural network based on learning data (for example, labeling data). A trained artificial neural network may be used in the online period subsequently.

Also, for example, the online period may denote a period where data is processed in real time, or a task corresponding to a real-time situation is performed. For example, a process (inference) of performing, by the computing system 1000, prediction on real data by using a pre-trained artificial neural network may be included in the online period.

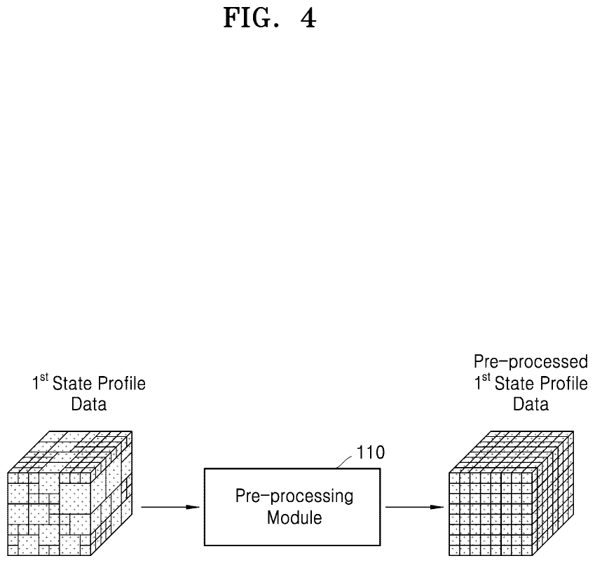

The pre-processing module 110 may pre-process state profile data based on a non-uniform grid representing a three-dimensional (3D) structure of a transistor and may thus generate state profile data based on a uniform grid representing the 3D structure of the transistor. A pre-processing method of the pre-processing module 110 will be described below in detail with reference to FIG. 4.

In an embodiment, the pre-processing module 110 may pre-process the first state profile data to generate pre-processed first state profile data. In some embodiments, the pre-processing module 110 may be configured to perform data pre-processing to improve functioning of the model 100. Such pre-processing may include, but is not limited to, aggregation (combining multiple state profile data items), attribute modification (removing portions of the state profile data that may be irrelevant or may have a minimal effect), and providing missing state profile data through interpolation or averaging.

Here, the pre-processed first state profile data may be state profile data of grids having an equal interval. Also, the first state profile data may be state profile data of grids having different intervals.

The encoding module 120 may convert input data into a latent space having a high dimension or a low dimension to generate encoded data.

In an embodiment, the encoding module 120 may perform an encoding operation on input data so as to adjust a dimension (e.g., a number of parameters) of the pre-processed first state profile data and/or the input data (for example, a target parameter), so that an operation of the Fourier layer module 130 is possible. In some embodiments, the encoding module 120 may be configured to perform dimensionality reduction, thereby reducing the size of the data set such that the model 100 may execute with decreased memory and/or computational requirements.

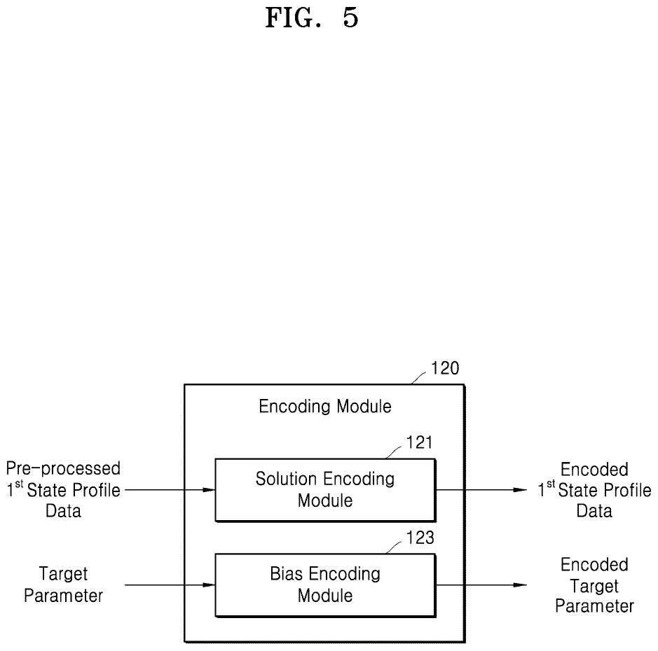

That is, the encoding module 120 may encode the target parameter and the pre-processed first state profile data to generate an encoded target parameter and encoded first state profile data. The encoding module 120 according to some embodiments will be described below in detail with reference to FIG. 5.

The Fourier layer module 130 may perform linear transformation and/or nonlinear transformation on encoded input data to generate result data, based on a parameter of an artificial neural network.

Here, the parameters of an artificial neural network may be referred to as parameters in an offline period and may be referred to as pre-trained parameters in an online period.

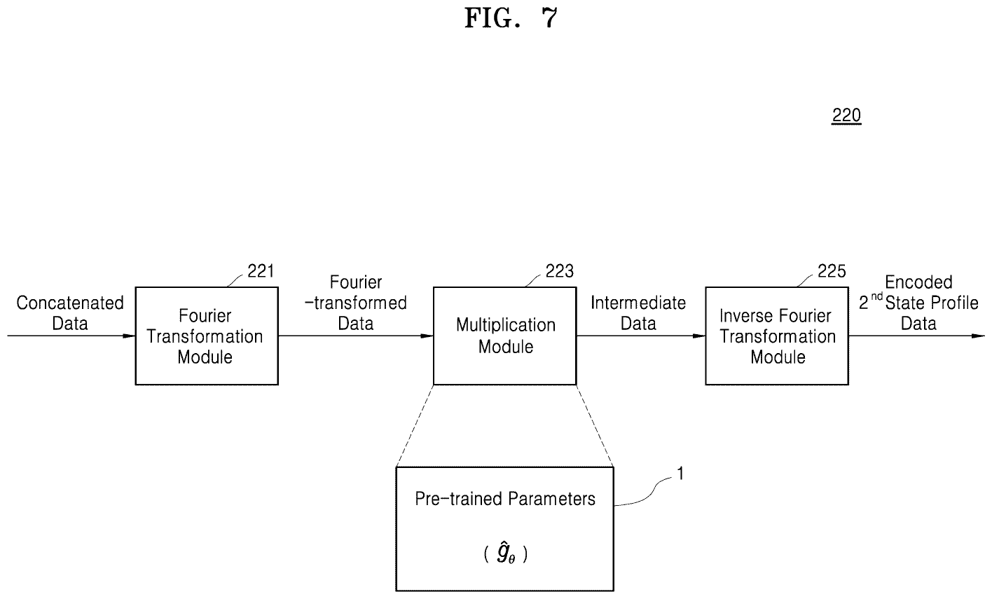

In the offline period, the parameters may be updated to emulate a Fourier-transformed function of a Green's function, based on labeled data. Here, the solution of the drift-diffusion equation described above may be expressed based on the Green's function. An operation of emulating the Fourier-transformed function of the Green's function by using the parameters will be described below in detail with reference to FIG. 7.

In the online period, the Fourier layer module 130 may generate result data from the encoded input data so as to emulate the Fourier-transformed function of the Green's function, based on the pre-trained parameters.

In an embodiment, in the online period, the Fourier layer module 130 (or the pre-trained artificial neural network) may be configured to generate encoded second state profile data, based on the encoded target parameter and the encoded first state profile data.

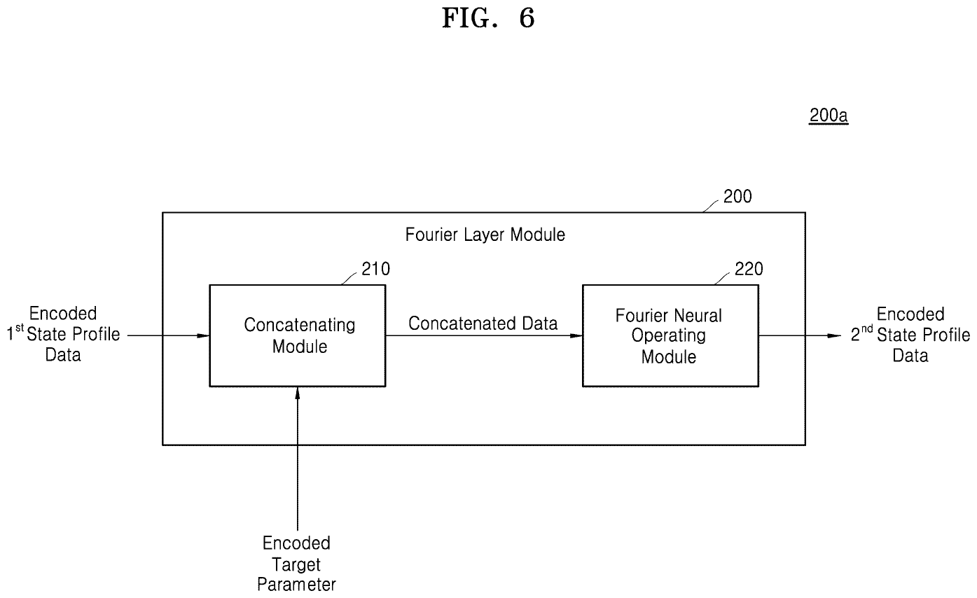

The Fourier layer module 130 according to some embodiments will be described below in detail with reference to FIGS. 6 to 9.

The decoding module 140 may perform a decoding operation opposite to an encoding operation of the encoding module 120. That is, the decoding module 140 may transform encoded data into an original input data dimension in the latent space to generate decoded data.

In an embodiment, the decoding module 140 may decode the encoded second state profile data to generate the second state profile data.

FIG. 4 is a diagram illustrating an operation of a pre-processing module 110 according to an embodiment.

The pre-processing module 110 may pre-process state profile data based on a non-uniform grid representing a 3D structure of a transistor and may thus generate state profile data based on a uniform grid representing the 3D structure of the transistor.

The pre-processing module 110 may perform an interpolation operation on state profile data so that the state profile data having a non-uniform grid has a uniform grid. In some embodiments, the pre-processing module 110 may perform an interpolation operation based on down-sampling and/or up-sampling on the state profile data, so that the state profile data has a uniform grid. Here, down-sampling may be based on max pooling, average pooling, and/or the like.

That is, the state profile data may be based on a non-uniform grid, and thus, a grid of the state profile data based on a non-uniform grid may be interpolated, thereby generating state profile data based on a uniform grid. The state profile data based on a uniform grid may be based on a Cartesian coordinate system and may include values respectively corresponding to X, Y, and Z.

In some embodiments, an attribute of a portion of a 3D structure may be considered. For example, a doping concentration may be considered in a substrate of a transistor. A portion, where an attribute is considered, of the 3D structure may be referred to as a region of interest (ROI). In some embodiments, in an interpolation operation, values corresponding to a region, except an ROI, of the 3D structure may be masked as a certain value. For example, values corresponding to a region, except the ROI, of the 3D structure in the state profile data may be set to 0 (zero).

Referring to FIG. 4, the pre-processed first state profile data may be state profile data of grids having an equal interval. Also, the first state profile data may be state profile data of grids having different intervals.

That is, the pre-processing module 110 may pre-process first state profile data to generate pre-processed first state profile data compatible with the computing system 1000 according to an embodiment.

FIG. 5 is a diagram illustrating an operation of an encoding module 120 according to an embodiment.

Referring to FIG. 5, the encoding module 120 may include a solution encoding module 121 and a bias encoding module 123.

Each of the solution encoding module 121 and the bias encoding module 123 may convert input data into a latent space having a low dimension or a high dimension to generate encoded data.

In an embodiment, the solution encoding module 121 may perform an encoding operation on input data so as to adjust a dimension of the pre-processed first state profile data, so that an operation of the Fourier layer module 130 is possible.

That is, the solution encoding module 121 may encode the pre-processed first state profile data to generate encoded first state profile data. In other words, the solution encoding module 121 may receive the pre-processed first state profile data as an input value and may provide the encoded first state profile data to the Fourier layer module 130.

In an embodiment, the bias encoding module 123 may perform an encoding operation on a target parameter so as to adjust a dimension of the target parameter, so that the operation of the Fourier layer module 130 is possible.

That is, the bias encoding module 123 may encode the target parameter to generate an encoded target parameter. In other words, the bias encoding module 123 may receive the target parameter as an input value and may provide the encoded target parameter to the Fourier layer module 130.

In some embodiments, in a case where the Fourier layer module 130 is implemented with a plurality of Fourier layer modules, the bias encoding module 123 may provide the encoded target parameter to each of a plurality of Fourier layer modules.

FIG. 6 is a diagram illustrating a Fourier layer module according to an embodiment. FIG. 7 is a diagram illustrating a Fourier operating module according to an embodiment.

The Fourier layer module 130 (or a pre-trained artificial neural network) described above with reference to FIG. 3 may be implemented with at least one Fourier layer module. That is, the pre-trained artificial neural network may include at least one Fourier layer module.

For example, the Fourier layer module 130 may be implemented with one Fourier layer module 130, or may be implemented with two or more Fourier layer modules 130.

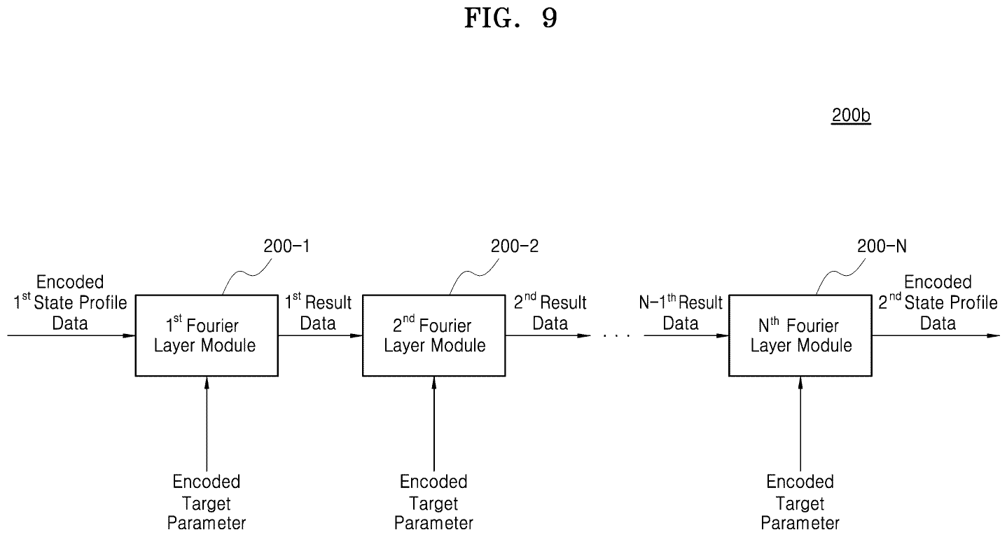

FIG. 6 is a diagram illustrating a pre-trained artificial neural network 200a implemented with one Fourier layer module 200, FIG. 7 is a diagram illustrating a Fourier neural operating module 220 included in a Fourier layer module 200, and FIG. 9 is a diagram illustrating a pre-trained artificial neural network 200b implemented with first to N^{th} Fourier layer modules 200-1 to 200-N. Here, N may be a positive integer of 2 or more.

Also, the Fourier layer module 200 and each of the first to N^{th} Fourier layer modules 200-1 to 200-N may have the same configuration. Therefore, the following descriptions of elements of the first to N^{th} Fourier layer modules 200-1 to 200-N illustrated in FIG. 9 may be applicable to the descriptions of the Fourier layer module 200 of FIG. 6 and the Fourier layer module 200 of FIG. 7, except for differences described below.

Hereinafter, the pre-trained artificial neural network 200a implemented with the one Fourier layer module 200 will be described.

Referring to FIG. 6, the Fourier layer module 200 may include a concatenating module 210 and a Fourier neural operating module 220.

The concatenating module 210 may concatenate first input data and second input data with each other to generate concatenated data.

Referring to FIG. 6, the concatenating module 210 may concatenate an encoded target parameter and encoded first state profile data with each other to generate concatenated data.

Here, concatenation may denote an operation of coupling two or more tensors as one tensor along a certain axis. That is, concatenation may denote an operation of coupling several vectors or matrixes as one longer vector or matrix. In some embodiments, the concatenation may include processing the tensors to find zeros in a tensor array, which can be excluded when performing computations so as to reduce computational requirements of the Fourier layer module 200.

In some embodiments, the concatenated data may be information where information represented by an encoded target parameter is coupled to information represented by encoded first state profile data.

Also, the concatenating module 210 may provide the generated concatenated data to the Fourier neural operating module 220.

The Fourier neural operating module 220 may be configured to generate encoded second state profile data, based on the concatenated data.

Referring to FIG. 7, the Fourier neural operating module 220 may include a Fourier transformation module 221, a multiplication module 223, and an inverse Fourier transformation module 225.

The Fourier transformation module 221 may perform Fourier transformation on the concatenated data to generate Fourier-transformed data.

The multiplication module 223 may perform multiplication of the Fourier-transformed data and pre-trained parameters 1 to generate intermediate data.

The inverse Fourier transformation module 225 may perform inverse Fourier transformation on the intermediate data to generate the encoded second state profile data.

Here, the pre-trained parameters 1 may be parameters which are pre-trained to emulate the Fourier-transformed function of the Green's function.

Hereinafter, an operation of emulating the Fourier-transformed function of the Green's function by using the pre-trained parameters 1 will be described in detail.

A PDE may be expressed based on the Green's function when an initial value and a boundary condition are assigned. That is, when the initial value and the boundary condition are assigned, a solution of a PDE may be assumed to be unique. In an embodiment, the initial value may correspond to the first state profile data, and the boundary condition may correspond to a target parameter. Here, the target parameter may be a target contact voltage Vᵢ.

For example, a solution of the drift-diffusion equation which is a PDE may be expressed based on the following Equation 1.

$${u}_{i} ( {ϕ}_{i} , {n}_{i} , {p}_{i} ; N ) ( r ) = {\int }_{Ω} {u}_{i - 1} ( ξ ) 𝒢 ( r , ξ ) d ξ + {\int }_{Ω} {h}_{i} ( ξ ) 𝒢 ( r , ξ ) d ξ \qquad [ Equation 1 ]$$

In Equation 1, uᵢ₋₁(ϕᵢ₋₁, nᵢ₋₁; pᵢ₋₁; N)(r) may represent the target value described above, Ω may represent a domain, uᵢ₋₁(ξ) may represent the initial value described above, [symbol] (r,Ξ), may represent the Green's function, and hᵢ(ξ) may represent the boundary condition.

Also, the boundary condition may be defined as the following Equation 2.

$${h}_{i} ( r ) = \{ \begin{matrix}{V}_{i} , & r ∈ δΩ \\ 0 , & otherwise\end{matrix} \qquad [ Equation 2 ]$$

In Equation 2, hᵢ(r) may represent the boundary condition, Vᵢ may represent a target contact voltage, and δΩ may represent a boundary of the domain.

An operation of directly solving Equation 1 may be unreal because of nonlinearity (i.e., because an integral operation has to be performed), and thus, in an embodiment, the following Equation 3 may be satisfied, and the following Equation 4 obtained by performing Fourier transformation and inverse Fourier transformation on the right side of Equation 1 may be used.

$$𝒢 ( x , ξ ) = 𝒢 ( x - ξ ) \qquad [ Equation 3 ]$$

When Equation 3 is satisfied, a kernel integral operation in Equation 1 may be equal to linear transformation in a Fourier space. According to an embodiment, state profile data based on a uniform grid generated by the pre-processing module 110 may be used, and thus, all pre-processed state profile data described herein may satisfy Equation 3.

$${u}_{i} ( {ϕ}_{i} , {n}_{i} , {p}_{i} ; N ) ( r ) ≃ {ℱ}^{- 1} ( ℱ ( 𝒢 ) \cdot ℱ ( {u}_{i - 1} + {h}_{i} ) ) ( r ) \qquad [ Equation 4 ]$$

Subsequently, referring to Equation 4, it may be seen that the solution of the drift-diffusion equation is based on “multiplication of the Fourier-transformed function [symbol] ( [symbol] ) of the Green's function [symbol] ″.

Therefore, the computing system 1000 may perform a process simulation by using the machine learning model 100 e.g., via direct calculation based on the doping profile, input voltage, and target voltage, with reduced data requirements in comparison to performing the process simulation using data-driven methods), based on the following Equation 5.

$${u}_{i} ( {ϕ}_{i} , {n}_{i} , {p}_{i} ; N ) ( r ) ≃ {ℱ}^{- 1} ( {ℱ ( \hat{𝒢} )}_{θ} \cdot ℱ ( {u}_{i - 1} + {h}_{i} ) ) ( r ) \qquad [ Equation 5 ]$$

That is, according to an embodiment, in an offline period, the computing system 1000 may train parameters [symbol] _{θ} of the Fourier neural operating module 220 so as to emulate the Fourier-transformed function [symbol] ( [symbol] ) of the Green's function of Equation 4, based on labeled data.

Here, the labeled data may be a set of state profile data satisfying the drift-diffusion equation, based on a certain voltage. That is, the labeled data may represent a set of mapped state profile data, based on a voltage or a set of voltages.

According to an embodiment, in an online period, the computing system 1000 may perform a multiplication of Fourier-transformed data corresponding to a value [symbol] (uᵢ₋₁+hᵢ))(r) and pre-trained parameters 1 [symbol] _{θ} corresponding to the Fourier-transformed function [symbol] ( [symbol] ) of the Green's function, and thus, may generate intermediate data corresponding to a Fourier-transformed function [symbol] ( [symbol] )_{θ}· [symbol] (uᵢ₋₁+hᵢ)(r) of a solution of a drift-diffusion equation in Equation 5. Subsequently, the inverse Fourier transformation module 225 may perform inverse Fourier transformation on the intermediate data to generate encoded second state profile data corresponding to the solution [symbol] ⁻¹( [symbol] ( [symbol] )_{θ}· [symbol] (uᵢ₋₁+hᵢ))(r) of the drift-diffusion equation in Equation 5.

Here, the value [symbol] (uᵢ₋₁+hᵢ))(r) may be based on an initial value uᵢ₋₁ corresponding to the first state profile data and a boundary condition hᵢ corresponding to the target parameter. Here, the target parameter may be a target contact voltage Vᵢ.

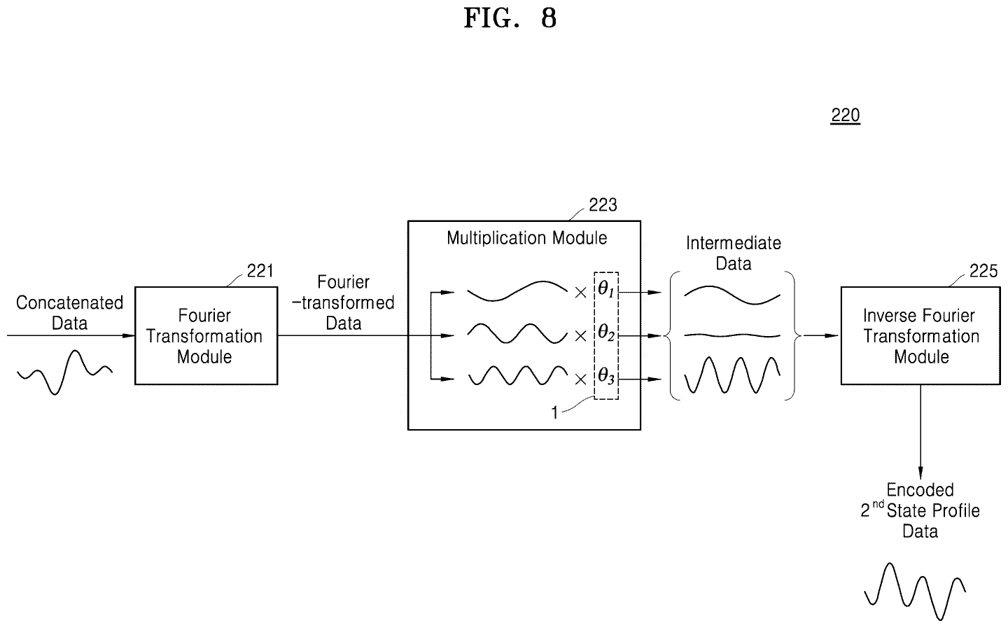

FIG. 8 is a diagram illustrating an operation of a Fourier operating module according to an embodiment.

The Fourier transformation module 221 may perform Fourier transformation on the concatenated data to generate Fourier-transformed data.

Here, the concatenated data may represent an aperiodic function, and the Fourier-transformed data may represent the sum of a plurality of periodic functions.

Referring to FIG. 8, an aperiodic function corresponding to concatenated data may be Fourier-transformed, and thus, Fourier-transformed data may represent a sum of first to third periodic functions corresponding to the aperiodic function described above.

The multiplication module 223 may perform a multiplication of the Fourier-transformed data and pre-trained parameters 1 to generate intermediate data. That is, the multiplication module 223 may perform a multiplication in a Fourier space, and thus, may emulate an integral in a Euclid space. That is, the multiplication module 223 may perform linear transformation on each of periodic functions in the Fourier space, based on the pre-trained parameters 1.

Each of the pre-trained parameters 1 may be a weight corresponding to a frequency of a periodic function.

Referring to FIG. 8, the pre-trained parameters 1 may include a weight corresponding to a frequency of each of the first to third periodic functions. For example, a first weight θ₁ may correspond to a first frequency of the first periodic function, a second weight θ₂ may correspond to a second frequency of the second periodic function, and a third weight θ₃ may correspond to a third frequency of the third periodic function. The multiplication module 223 may multiply the first weight θ₁ and the first periodic function, multiply the second weight θ₂ and the second periodic function, and multiply the third weight θ₃ and the third periodic function and may summate multiplication results, thereby generating intermediate data.

The inverse Fourier transformation module 225 may perform inverse Fourier transformation on the intermediate data to generate the encoded second state profile data.

Here, the intermediate data may represent the sum of linear-transformed periodic functions in the Fourier space, based on the pre-trained parameters 1, and the encoded second state profile data may represent an aperiodic function obtained by performing inverse Fourier transformation on the sum of linear-transformed periodic functions in the Fourier space.

Referring to FIG. 8, by performing inverse Fourier transformation on the sum of linear-transformed periodic functions in the Fourier space corresponding to the intermediate data, the encoded second state profile data may represent an aperiodic function corresponding to an encoded target value uᵢ.

FIG. 9 is a diagram illustrating a Fourier layer module according to another embodiment.

FIG. 6 is a diagram illustrating a pre-trained artificial neural network 200a implemented with one Fourier layer module 200, FIG. 7 is a diagram illustrating a Fourier neural operating module 220 included in a Fourier layer module 200, and FIG. 9 is a diagram illustrating a pre-trained artificial neural network 200b implemented with first to N^{th} Fourier layer modules 200-1 to 200-N. Here, N may be a positive integer of 2 or more.

Also, the Fourier layer module 200 and each of the first to N^{th} Fourier layer modules 200-1 to 200-N may have the same configuration. Therefore, the following descriptions of elements of the first to N^{th} Fourier layer modules 200-1 to 200-N illustrated in FIG. 9 may be applicable to the descriptions of the Fourier layer module 200 of FIG. 6 and the Fourier layer module 200 of FIG. 7, except for differences noted herein.

Hereinafter, the pre-trained artificial neural network 200b implemented with the first to N^{th} Fourier layer modules 200-1 to 200-N will be described.

The pre-trained artificial neural network 200b may include a plurality of Fourier layer modules. Referring to FIG. 9, the pre-trained artificial neural network 200b may include the first to N^{th} Fourier layer modules 200-1 to 200-N. Here, N may be an integer of 2 or more.

The plurality of Fourier layer modules may receive, as an input value, one of the encoded target parameters and the encoded first state profile data or result data of a previous Fourier layer module and may generate result data of a corresponding Fourier layer module or encoded second state profile data.

As used herein, a previous Fourier layer module may include a Fourier layer module whose result was calculated at a previous point in time. For example, the plurality of Fourier layer modules N may use an input value, target parameter, or other characteristics of a previous Fourier layer module either directly prior (F-1) or otherwise preceding (F-2, F-3, F−X) the current Fourier layer module F, where X may be any number less than N. As used herein, a corresponding Fourier layer module may include another Fourier layer module related or unrelated to the plurality of Fourier layer modules. For example, in one embodiment, for a current Fourier layer module F in the plurality of Fourier layer modules N, the corresponding Fourier layer module may refer to F−X, F+X, where X may be any number less than N, and F maybe any number less than or equal to N.

Referring to FIG. 9, each of the first to N^{th} Fourier layer modules 200-1 to 200-N may receive the encoded target parameter as an input value.

Referring to FIG. 9, the first Fourier layer module 200-1 may receive the encoded first state profile data as an input value and may generate first result data, based on the encoded target parameter and the encoded first state profile data. A method of generating the first result data by using the first Fourier layer module 200-1 may be the same as a method of generating the encoded second state profile data by using the Fourier layer module 200 described above with reference to FIG. 7.

Referring to FIG. 9, the second Fourier layer module 200-2 may receive, as an input value, the first result data which is result data of a previous Fourier layer module and may generate second result data, based on the encoded target parameter and the first result data. Here, a method of generating the second result data by using the second Fourier layer module 200-2 may be the same as a method of generating the encoded second state profile data by using the Fourier layer module 200 described above with reference to FIG. 7, other than that the encoded first state profile data (which is an input value) is transformed into the first result data (which is result data of a previous Fourier layer module).

Referring to FIG. 9, the N^{th} Fourier layer module 200-N may receive, as an input value, N−1^{th} result data which is result data of a previous Fourier layer module and may generate encoded second state profile data, based on the encoded target parameter and the N−1^{th} result data. Here, a method of generating the encoded second state profile data by using the N^{th} Fourier layer module 200-N may be the same as a method of generating the encoded second state profile data by using the Fourier layer module 200 described above with reference to FIG. 7, other than that the encoded first state profile data (which is an input value) is transformed into the N−1^{th} result data (which is result data of a previous Fourier layer module).

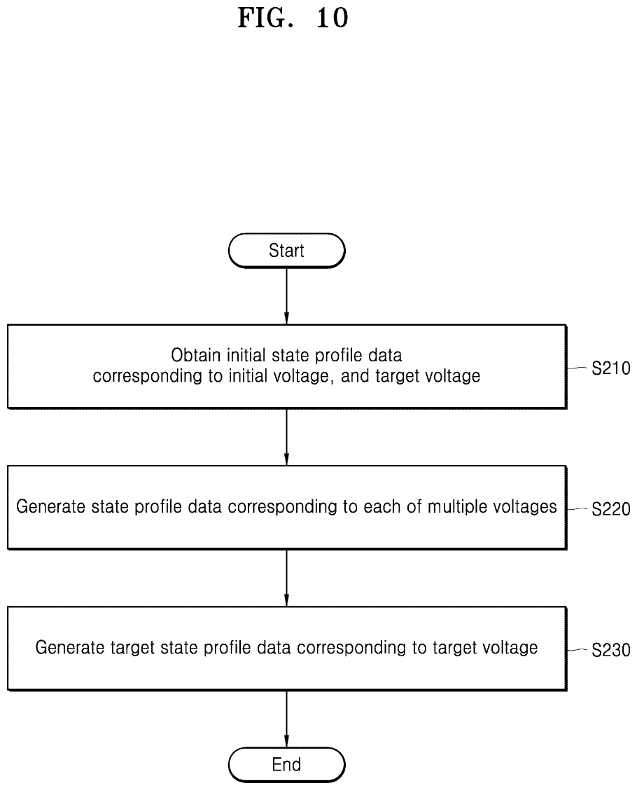

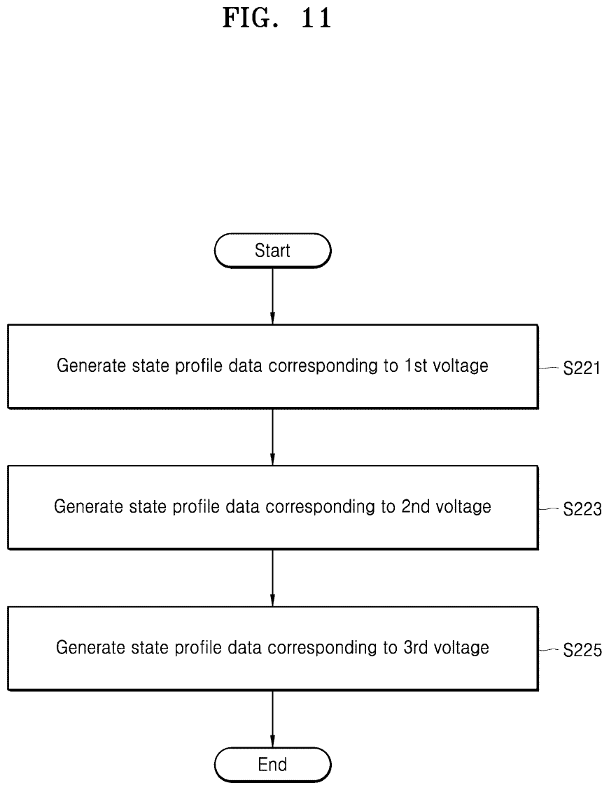

FIG. 10 is a flowchart illustrating an example of an operation of a computing system according to another embodiment. FIG. 11 is a flowchart illustrating in more detail operation S220 of FIG. 10.

An operation of the computing system 1000 described with reference to FIGS. 10 and 11 may correspond to a modification example of an operation of the computing system 1000 described above with reference to FIGS. 1 to 9. Hereinafter, in the following descriptions of FIGS. 10 and 11, descriptions which are the same as or similar to the descriptions of FIGS. 1 to 9 may be omitted.

Referring to FIG. 10, in operation S210, the computing system 1000 may obtain a target voltage and initial state profile data corresponding to an initial voltage.

Referring to FIG. 10, in operation S220, the computing system 1000 may generate state profile data corresponding to each of a plurality of voltages, based on the machine learning model 100. Here, a value of each of the plurality of voltages may be between a value of the initial voltage and the target voltage.

For example, referring to FIG. 11, operation S220 may include operation S221 of generating state profile data corresponding to a first voltage by using the computing system 1000, based on the machine learning model 100, operation S223 of generating state profile data corresponding to a second voltage by using the computing system 1000, based on the machine learning model 100, and operation S225 of generating state profile data corresponding to a third voltage by using the computing system 1000, based on the machine learning model 100.

Here, a difference between a value of the first voltage and a value of the second voltage may be the same as a difference between the value of the second voltage and a value of the third voltage.

In an embodiment, in operation S221, the computing system 1000 may generate state profile data corresponding to the first voltage, based on the initial value. In operation S223, the computing system 1000 may generate state profile data corresponding to the second voltage, based on the state profile data corresponding to the first voltage. In operation S225, the computing system 1000 may generate state profile data corresponding to the third voltage, based on the state profile data corresponding to the second voltage. Subsequently, the computing system 1000 may generate state profile data corresponding to the target voltage, based on the state profile data corresponding to the third voltage.

That is, the computing system 1000 may generate state profile data corresponding to a corresponding voltage, based on a uniform voltage interval. For example, the computing system 1000 may generate state profile data corresponding to a corresponding voltage by 0.5 V units.

Referring again to FIG. 10, in operation S230, the computing system 1000 may generate state profile data corresponding to the target voltage, based on the machine learning model 100.

Here, the computing system 1000 may generate state profile data corresponding to a corresponding voltage from the initial voltage, based on the uniform voltage interval, and then, when reaching the target voltage, the computing system 1000 may generate state profile data corresponding to the target voltage.

A method of generating the second state profile data described above with reference to FIGS. 1 to 9 may be applied to a method of generating state profile data corresponding to a corresponding voltage described above.

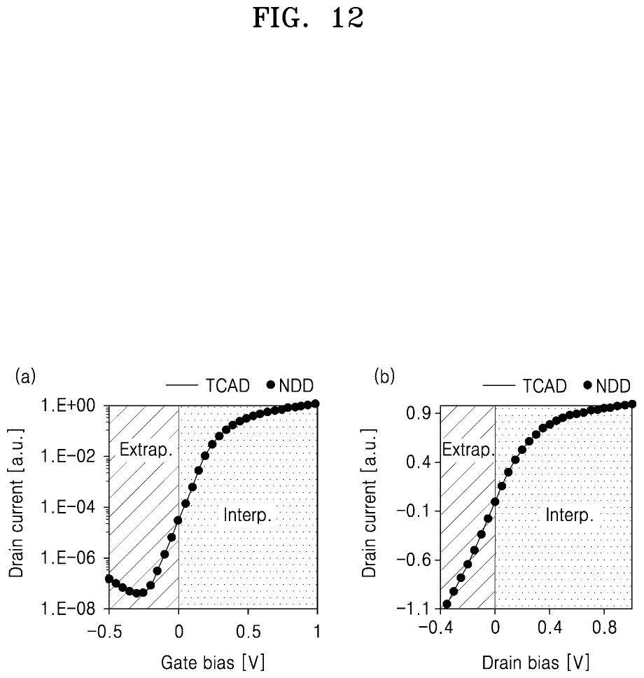

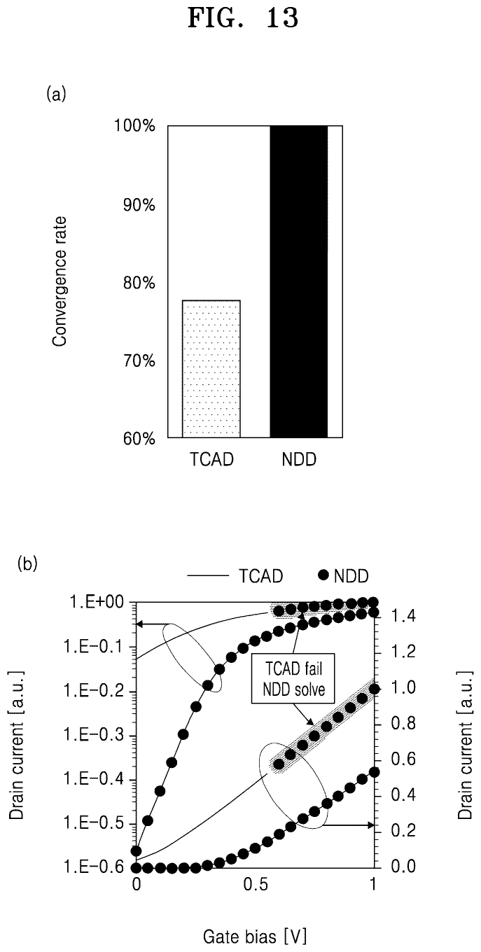

FIG. 12 is a graph showing an output value with respect to an input value where a machine learning model according to an embodiment is outside a learning range. FIG. 13 is a diagram to describe a convergence rate of a machine learning model according to an embodiment. Here, the machine learning model 100 described above may be referred to as a numerical data processor (NDD), and the TCAD simulator according to the comparative example may be referred to as a TCAD.

Referring to FIG. 12, it may be seen that the NDD has been trained from 0 V up to 1 V, and a drain current from −0.5 V up to 0 V which is a period of an input value outside a learning range is shown as a graph. In other words, it may be seen that the NDD has been trained from 0 V to 1 V as indicated in the graph as the shaded interpolation area abbreviated “Interp.” From −0.5 V to 0 V it can be see that the NDD is operating in a range of input values that is outside the learning range as indicated in the graph as the shaded extrapolation area abbreviated “Extrap.” FIG. 12 (a) is a graph where a gate bias is set to an independent variable, and FIG. 12 (b) is a graph where a drain bias is set to an independent variable. Referring to FIG. 12, it may be seen that both of (a) and (b) include a shaded region which indicates a range of values in which the NDD is untrained, referred to as the extrapolation period or range (Extrap.). In other words, the extrapolation range indicated by the shaded region labeled “Extrap.” refers to the range of input values in which the NDD is untrained and thus the NDD predicts and/or estimates the values in a range outside of known data range by extrapolation.

Referring to FIG. 13, it may be seen that the TCAD can be replaced with an NDD. Even when the TCAD does not solve a PDE, the NDD may provide an accurate solution. In other words, in ranges where the TCAD does not provide a solution, the NDD may provide an accurate solution.

In detail, referring to FIG. 13 (a), when the TCAD succeeds by only 78% in convergence, the NDD may succeed up to 100% in convergence. Moreover, referring to FIG. 13 (b), even when the TCAD may not perform calculations, it may be seen that the NDD may calculate the drain current with respect to the gate bias.

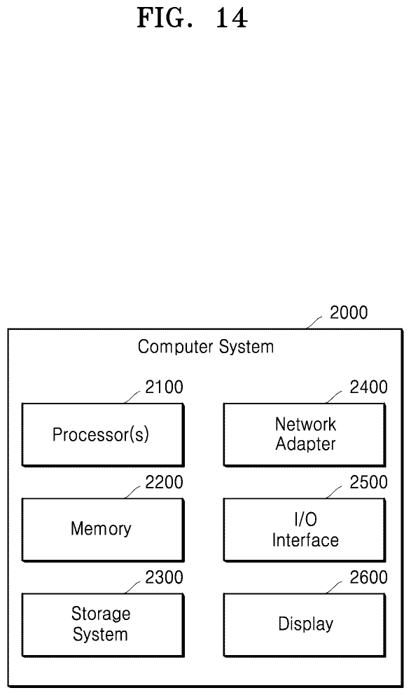

FIG. 14 is a block diagram illustrating a computer system 2000 according to an embodiment.

In some embodiments, the computer system 2000 of FIG. 1 may perform training of the machine learning models described above with reference to the drawings and may be referred to as a semiconductor simulator system or a training system.

The computer system 2000 may be referred to as a hardware system including a general-purpose or special-purpose computing system. For example, the computer system 2000 may include a personal computer, a server computer, a laptop computer, and appliances. As illustrated in FIG. 14, the computer system 2000 may include at least one processor 2100, a memory 2200, a storage system 2300, a network adapter 2400, an input/output (I/O) interface 2500, and a display 2600.

The at least one processor 2100 may execute a program module including a computer system-executable instruction. The program module may include routines, programs, objects, components, a logic, and a data structure, which perform a certain task or implement a certain data type. The memory 2200 may include a computer system-readable medium of a non-volatile memory type such as random access memory (RAM). The at least one processor 2100 may access the memory 2200 and may execute instructions loaded into the memory 2200. The storage system 2300 may non-volatilely store information, and in some embodiments, may include at least one program product including a program module configured to perform training of the machine learning models described above with reference to the drawings. In a non-limiting embodiment, a program may include an operating system, at least one application, and the other program modules and program data.

The network adapter 2400 may provide access to a local area network (LAN), a wide area network (WAN), and/or a common network (for example, the Internet). The I/O interface 2500 may provide a communication channel with a peripheral device such as a keyboard, a pointing device, or an audio system. The display 2600 may output various information so as to be checked by a user.

In some embodiments, training of the machine learning models described above with reference to the drawings may be implemented by a computer program product. The computer program product may include a non-transitory computer-readable medium (or storage medium) including computer-readable program instructions for allowing the at least one processor 2100 to perform image processing and/or training of models. In a non-limiting embodiment, the computer-readable instruction may be an assembler instruction, an instruction set architecture (ISA) instruction, a machine instruction, a machine-dependent instruction, a firmware instruction, state setting data, or object code or source code written in at least one programming language.

The computer-readable medium may be a non-transitory type of medium which may non-transiently retain and store instructions executed by an instruction-executable device or the at least one processor 2100. The computer-readable medium may be an electronic storage device, a magnetic storage device, an optical storage device, an electromagnetic storage device, a semiconductor storage device, or a combination thereof, but is not limited thereto. For example, the computer-readable medium may be a portable computer disk, a hard disc, dynamic access memory (RAM), read-only memory (ROM), electrically erasable read only memory (EEPROM), flash memory, static RAM (SRAM), a compact disc (CD), a digital video disc (DVD), a memory stick, a floppy disc, a mechanically encoded device such as a punch card, or a combination thereof.

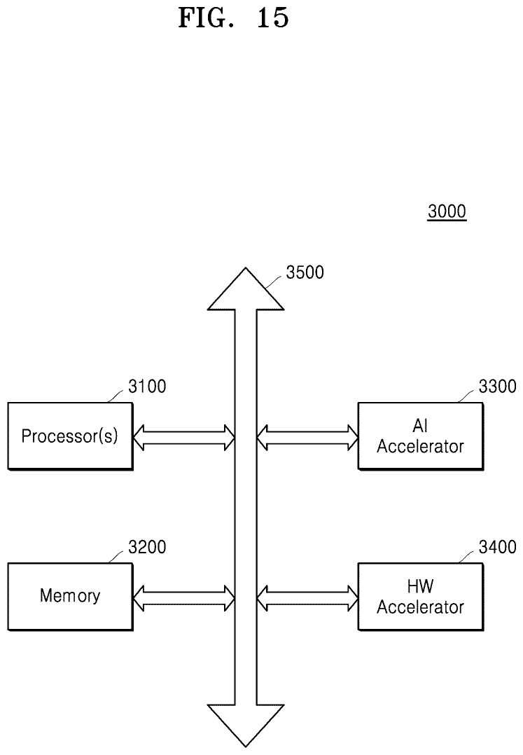

FIG. 15 is a block diagram illustrating a system 3000 according to an embodiment.

In some embodiments, a machine learning model according to an embodiment may be executed by the system 3000. Therefore, the system 300 may have low complexity and may quickly generate an accurate result.

Referring to FIG. 15, the system 3000 may include at least one processor 3100, a memory 3200, an artificial intelligence (AI) accelerator 3300, and a hardware accelerator 3400, and the at least one processor 3100, the memory 3200, the AI accelerator 3300, and the hardware accelerator 3400 may communicate with each other through a bus 3500. In some embodiments, the at least one processor 3100, the memory 3200, the AI accelerator 3300, and the hardware accelerator 3400 may be included in one semiconductor chip. Also, in some embodiments, at least two of the at least one processor 3100, the memory 3200, the AI accelerator 3300, and the hardware accelerator 3400 may be respectively included in two or more semiconductor chips mounted on a board.

The at least one processor 3100 may execute instructions. For example, the at least one processor 3100 may execute instructions stored in the memory 3200, and thus, may execute an operating system or may execute applications executed by the operating system. In some embodiments, the at least one processor 3100 may execute instructions, and thus, may instruct the AI accelerator 3300 and/or the hardware accelerator 3400 to perform an operation and may obtain a performance result of the operation from the AI accelerator 3300 and/or the hardware accelerator 3400. In some embodiments, the at least one processor 3100 may be an application specific instruction processor (ASIP) which is customized for certain use and may support a dedicated instruction set.

The memory 3200 may have a structure which stores data. For example, the memory 3200 may include a volatile memory device such as dynamic RAM (DRAM) or SRAM, or may include a non-volatile memory device such as flash memory or resistive RAM (RRAM). The at least one processor 3100, the AI accelerator 3300, and the hardware accelerator 3400 may store data (for example, IN, IMG_I, IMG_O, and OUT of FIG. 2) in the memory 3200 through the bus 3500, or may read data (for example, IN, IMG_I, IMG_O, and OUT of FIG. 2) from the memory 3200.

The AI accelerator 3300 may denote hardware which is designed for AI applications. In some embodiments, the AI accelerator 3300 may include a neural processing unit (NPU) for implementing a neuromorphic structure, and the AI accelerator 3300 may process input data provided from the at least one processor 3100 and/or the hardware accelerator 3400 and may provide data to the at least one processor 3100 and/or the hardware accelerator 3400. In some embodiments, the AI accelerator 3300 may be programmable and may be programmed by the at least one processor 3100 and/or the hardware accelerator 3400.

The hardware accelerator 3400 may denote hardware which is designed for performing a certain operation at a high speed. For example, the hardware accelerator 3400 may be designed to perform data transformation such as demodulation, modulation, encoding, or decoding at a high speed. The hardware accelerator 3400 may be programmable and may be programmed by the at least one processor 3100 and/or the hardware accelerator 3400.

In some embodiments, the AI accelerator 3300 may execute the machine learning models described above with reference to the drawings. For example, the AI accelerator 3300 may execute each of the layers described above. The AI accelerator 3300 may process an input parameter, a feature map, and/or the like and may thus generate an output including useful information, such as simulation results indicating characteristics of a semiconductor device, which may be used to improve semiconductor device fabrication processes, apparatus, and/or semiconductor devices produced thereby. Also, in some embodiments, at least some of models executed by the AI accelerator 3300 may be executed by the at least one processor 3100 and/or the hardware accelerator 3400.

Hereinabove, embodiments have been described in the drawings and the specification. Embodiments have been described by using the terms described herein, but this has been merely used for describing the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept. Accordingly, the scope of the inventive concept may be defined based on the spirit and scope of the following claims.

While the inventive concept has been particularly shown and described with reference to embodiments thereof, it will be understood that various changes in form and details may be made therein without departing from the scope of the following claims.

What is claimed is:

1. A computer-implemented method of performing a process simulation of a semiconductor device, the method comprising:
executing, by at least one processor, computer program instructions to perform operations comprising:
obtaining a target parameter and first state profile data corresponding to an initial value; and
generating second state profile data corresponding to the target parameter from the first state profile data, based on a machine learning model,
wherein each of the first state profile data and the second state profile data represents an attribute profile of a corresponding state of the semiconductor device.

2. The computer-implemented method of claim 1, wherein the initial value is an initial voltage to be applied to the semiconductor device,
the target parameter is a target voltage to be applied to the semiconductor device,
the generating of the second state profile data comprises generating state profile data corresponding to each of a plurality of voltages, and
a value of each of the plurality of voltages is between a value of the initial voltage and a value of the target voltage,
wherein the value of each of the plurality of voltages is outside of a learning range of the machine learning model.

3. The computer-implemented method of claim 2, wherein the generating of the state profile data corresponding to each of the plurality of voltages comprises:
generating state profile data corresponding to a first voltage included in the plurality of voltages;
generating state profile data corresponding to a second voltage included in the plurality of voltages; and
generating state profile data corresponding to a third voltage included in the plurality of voltages, and
wherein a difference between a value of the first voltage and a value of the second voltage is equal to a difference between the value of the second voltage and a value of the third voltage, and wherein the first voltage, the second voltage, and the third voltage are in an extrapolation range of the machine learning model.

4. The computer-implemented method of claim 1, wherein the initial value corresponds to an initial value of a partial differential equation, and a solution of the partial differential equation is expressed based on a Green's function,
wherein the machine learning model comprises an artificial neural network, and
wherein the operations the method further comprise pre-training the neural artificial network to emulate a Fourier-transformed function of the Green's function, based on labeled data.

5. The computer-implemented method of claim 1, wherein the machine learning model comprises:
a pre-processing module configured to pre-process the first state profile data to generate pre-processed first state profile data;
an encoding module configured to encode the target parameter and the pre-processed first state profile data to generate an encoded target parameter and encoded first state profile data, respectively;
a pre-trained artificial neural network configured to generate encoded second state profile data, based on the encoded first state profile data and the encoded target parameter; and
a decoding module configured to decode the encoded second state profile data to generate the second state profile data.

6. The computer-implemented method of claim 5, wherein the pre-processed first state profile data is state profile data of grids having an equal interval.

7. The computer-implemented method of claim 5, wherein the pre-trained artificial neural network comprises at least one Fourier layer module, and
each of the at least one Fourier layer module comprises:
a concatenating module configured to concatenate one of the encoded first state profile data or result data of a previous Fourier layer module with the encoded target parameter to generate concatenated data; and
a Fourier neural operating module configured to generate the encoded second state profile data or result data of a corresponding Fourier layer module, based on the concatenated data.

8. The computer-implemented method of claim 7, wherein the Fourier neural operating module comprises:
a Fourier transformation module configured to perform a Fourier transformation on the concatenated data to generate Fourier-transformed data;
a multiplication module configured to perform a multiplication of the Fourier-transformed data and pre-trained parameters to generate intermediate data; and
an inverse Fourier transformation module configured to perform an inverse Fourier transformation on the intermediate data to generate the encoded second state profile data or the result data of the corresponding Fourier layer module.

9. The computer-implemented method of claim 8, wherein the initial value corresponds to an initial value of a partial differential equation, and a solution of the partial differential equation is expressed based on a Green's function, and
the pre-trained parameters are pre-trained to emulate a Fourier-transformed function of the Green's function.

10. A system comprising:
the at least one processor; and
a non-transitory computer-readable storage medium configured to store the computer program instructions allowing the at least one processor to perform the computer-implemented method of performing the process simulation of the semiconductor device of claim 1, when executed by the at least one processor.

11. A non-transitory computer-readable storage medium comprising the computer program instructions, wherein the computer program instructions, when executed by the at least one processor, are configured to allow the at least one processor to:
obtain a target parameter and first state profile data corresponding to an initial value; and generate second state profile data corresponding to the target parameter from the first state profile data, based on a machine learning model,
wherein each of the first state profile data and the second state profile data represents an attribute profile of a corresponding state of a semiconductor device.

12. A computing system comprising:
a processing circuit configured to obtain a target parameter and first state profile data corresponding to an initial value and generate second state profile data corresponding to the target parameter from the first state profile data, based on a machine learning model,
wherein each of the first state profile data and the second state profile data represents an attribute profile of a corresponding state of a semiconductor device.

13. The computing system of claim 12, wherein the initial value is an initial voltage to be applied to the semiconductor device,
the target parameter is a target voltage to be applied to the semiconductor device,
the processing circuit is configured to generate state profile data corresponding to each of a plurality of voltages, and
a value of each of the plurality of voltages is between a value of the initial voltage and a value of the target voltage,
wherein the value of each of the plurality of voltages is outside of a learning range of the machine learning model.

14. The computing system of claim 13, wherein the processing circuit is configured to generate state profile data corresponding to a first voltage included in the plurality of voltages, generate state profile data corresponding to a second voltage included in the plurality of voltages, and generate state profile data corresponding to a third voltage included in the plurality of voltages, and
wherein a difference between a value of the first voltage and a value of the second voltage is equal to a difference between the value of the second voltage and a value of the third voltage, and wherein the first voltage, the second voltage, and the third voltage are in an extrapolation range of the machine learning model.

15. The computing system of claim 12, wherein the initial value corresponds to an initial value of a partial differential equation, and a solution of the partial differential equation is expressed based on a Green's function,
wherein the machine learning model comprises an artificial neural network, and
wherein the artificial neural network is pre-trained to emulate a Fourier-transformed function of the Green's function, based on labeled data.

16. The computing system of claim 12, wherein the processing circuit comprises:
a pre-processing circuit configured to pre-process the first state profile data to generate pre-processed first state profile data;
an encoding circuit configured to encode the target parameter and the pre-processed first state profile data to generate an encoded target parameter and encoded first state profile data, respectively;
a pre-trained artificial neural network configured to generate encoded second state profile data, based on the encoded first state profile data and the encoded target parameter; and
a decoding circuit configured to decode the encoded second state profile data to generate the second state profile data.

17. The computing system of claim 16, wherein the pre-processed first state profile data is state profile data of grids having an equal interval.

18. The computing system of claim 16, wherein the pre-trained artificial neural network comprises at least one Fourier layer module, and
each of the at least one Fourier layer module comprises:
a concatenating module configured to concatenate one of the encoded first state profile data or result data of a previous Fourier layer module with the encoded target parameter to generate concatenated data; and
a Fourier neural operating module configured to generate the encoded second state profile data or result data of a corresponding Fourier layer module, based on the concatenated data.

19. The computing system of claim 18, wherein the Fourier neural operating module comprises:
a Fourier transformation circuit configured to perform a Fourier transformation on the concatenated data to generate Fourier-transformed data;
a multiplication circuit configured to perform a multiplication of the Fourier-transformed data and pre-trained parameters to generate intermediate data; and
an inverse Fourier transformation circuit configured to perform an inverse Fourier transformation on the intermediate data to generate the encoded second state profile data or the result data of the corresponding Fourier layer module.

20. The computing system of claim 19, wherein the initial value corresponds to an initial value of a partial differential equation, and a solution of the partial differential equation is expressed based on a Green's function,
the pre-trained parameters are pre-trained to emulate a Fourier-transformed function of the Green's function.
